(19) United States
(12) Patent Application Publication
(10) Pub. No.: US 2026/0256001 A1
(43) Pub. Date: Aug. 27, 2026

(54) INTEGRATED CIRCUIT INTERPOSER SYSTEM, METHOD AND DEVICE INCLUDED EMBEDDED PASSIVE COMPONENTS

(71) Applicant: Marvell Asia Pte Ltd, Singapore (SG)

(72) Inventor: Runzi Chang, Saratoga, CA (US)

(21) Appl. No.: 19/546,261

(22) Filed: Feb. 20, 2026

Related U.S. Application Data
(60) Provisional application No. 63/763,210, filed on Feb. 25, 2025.

(51) Int. Cl. H10W 70/68; H10B 80/00; H10D 80/30; H10W 44/00; H10W 70/05; H10W 70/695; H10W 90/00; H10W 90/10

(52) U.S. Cl. CPC H10W 70/681; H10W 44/601; H10W 70/093; H10W 90/10; H10W 90/724; H10B 80/00; H10D 80/30; H10W 70/695

(57) ABSTRACT

An interposer system, method and device including an interposer including a redistribution layer having a plurality of conductive pathways and passive electrical components positioned within the redistribution layer, wherein the redistribution layer electrically couples electrical devices with the passive components and/or a substrate.

### RELATED APPLICATIONS

This application claims priority under 35 U.S.C. § 119(e) of the co-pending U.S. provisional patent application Ser. No. 63/763,210 filed Feb. 25, 2025, and titled “Novel Chip Interposer with Embedded High Density Capacitors and Passive Components,” which is hereby incorporated by reference.

### FIELD OF INVENTION

The present invention relates to integrated circuit interposer systems, methods and devices. More particularly, the present invention relates to an interposer of an integrated circuit having embedded passive components.

### BACKGROUND OF THE INVENTION

The rapid advancement of semiconductor technology has led to increased demand for high-performance, compact, and efficient electronic systems. One of the key challenges in modern electronics is managing power distribution and signal integrity within densely packed integrated circuits (ICs). To address these challenges, the development of interposers for providing electrical coupling between a circuit substrate and microchips coupled to the substrate. However, microchips placed on organic interposers must utilize larger metal wires and larger spacing and thus lack the needed microchip performance and signal integrity needed for high speed datacenter microchips and systems (e.g. Artificial Intelligence Data Centers). Microchips on silicon interposers have smaller metal wires and smaller spacing, but suffer from higher cost and worse signal integrity due to the silicon substrate characteristics (e.g. high-K and polarization) and the necessary use of through silicon vias (TSV).

### BRIEF SUMMARY OF THE INVENTION

An interposer system, method and device including an interposer including a redistribution layer having a plurality of conductive pathways and passive electrical components positioned within the redistribution layer, wherein the redistribution layer electrically couples electrical devices with the passive components and/or a substrate.

A first aspect is directed to an integrated circuit system. The system comprises a substrate including a circuit, one or more electrical devices and an organic interposer electrically coupled with the electrical devices via a plurality of micro-bumps and electrically coupled with the substrate via a plurality of electrical contacts, the organic interposer including a redistribution layer forming a plurality of conductive pathways and one or more passive electrical components positioned within the redistribution layer, wherein the redistribution layer electrically couples the electrical devices with the circuit.

In some embodiments, the passive electrical components comprise high-density capacitors. In some embodiments, the high-density capacitors are coupled with the electrical devices via the conductive pathways of the redistribution layer. In some embodiments, the high-density capacitors are coupled with the electrical devices via the micro-bumps. In some embodiments, each high-density capacitor of the high-density capacitors is positioned within the redistribution layer adjacent to one of the electrical devices to which the high-density capacitor is electrically coupled. In some embodiments, the electrical devices comprise at least one of computing chiplets and memory chiplets. In some embodiments, the organic interposer is formed of one of polyimide and flame retardant 4. In some embodiments, the system further comprises one or more high density silicon electrical interconnects embedded within the redistribution layer and electrically coupled with the electrical devices. In some embodiments, the electrical contacts comprise a plurality of controlled collapse chip connection bumps.

A second aspect is directed to an organic interposer for use in a high-performance computing circuits. The organic interposer comprises an organic body having a top surface including a plurality of micro-bumps and a bottom surface including a plurality of electrical contacts, a redistribution layer formed within the organic body and including a plurality of conductive pathways and one or more passive electrical components positioned within the redistribution layer, wherein the redistribution layer electrically couples the micro-bumps with the electrical contacts.

In some embodiments, the passive electrical components comprise high-density capacitors. In some embodiments, the high-density capacitors are coupled with the micro-bumps via the conductive pathways of the redistribution layer. In some embodiments, the high-density capacitors are directly coupled with the micro-bumps. In some embodiments, each high-density capacitor of the high-density capacitors is positioned within the redistribution layer adjacent to a set of the micro-bumps to which the high-density capacitor is electrically coupled. In some embodiments, the organic body is formed of one of polyimide and flame retardant 4. In some embodiments, the interposer further comprises one or more high density silicon electrical interconnects embedded within the redistribution layer and electrically coupled with the micro-bumps. In some embodiments, the electrical contacts comprise a plurality of controlled collapse chip connection bumps.

Another aspect is directed to a method of fabricating an integrated circuit. The method comprises coupling a first surface of a body of an organic interposer to a carrier substrate, depositing an initial set of redistribution layers within the body, the initial set of redistribution layers including a plurality of conductive pathways surrounding one or more reserved areas intended for one or more passive electrical components, removing dielectric material from the one or more areas and embedding the passive electrical components within the initial set of redistribution layers within the reserved areas, depositing a plurality of micro-bumps onto a second surface of the body of the organic interposer and electrically coupling one or more electrical devices to the micro-bumps.

In some embodiments, the passive electrical components comprise high-density capacitors. In some embodiments, the method further comprises electrically coupling the micro-bumps to the high-density capacitors such that the high-density capacitors are electrically coupled with the electrical devices via the micro-bumps. In some embodiments, the method further comprises, before depositing the plurality of micro-bumps, covering a top of the initial set of redistribution layers and at least one of the high-density capacitors with a top set of redistribution layers. In some embodiments, the method further comprises electrically coupling the redistribution layer to the micro-bumps and the high-density capacitors such that the high-density capacitors are electrically coupled with the electrical devices via the redistribution layer and the micro-bumps. In some embodiments, the embedding the passive electrical components within the initial set of redistribution layers comprises positioning each high-density capacitor of the high-density capacitors adjacent to one of the electrical devices to which the high-density capacitor is electrically coupled. In some embodiments, the method further comprises removing the carrier substrate from the first surface of the body, couple another carrier substrate with the second surface, covering a bottom of the initial set of redistribution layers with a bottom set of redistribution layers, wherein the initial set, the bottom and the top of the redistribution layers form a full redistribution layer, depositing a plurality of electrical contacts on the first surface of the body and electrically coupling the electrical contacts with the one or more devices via the full redistribution layer. In some embodiments, the electrical devices comprise at least one of computing chiplets and memory chiplets. In some embodiments, the organic interposer is formed of one of polyimide and flame retardant 4. In some embodiments, the method further comprises embedding one or more high density silicon electrical interconnects within the reserved areas of the redistribution layer and electrically coupling the high density silicon electrical interconnects with the electrical devices. In some embodiments, the electrical contacts comprise a plurality of controlled collapse chip connection bumps.

Another aspect is directed to an integrated circuit system. The system comprises means for supporting a circuit including a circuit, means for computing and organic means for electrically coupling electrically coupled with the means for computing via a plurality of micro-bumps and electrically coupled with the means for supporting via a plurality of electrical contacts, the means for electrically coupling including a redistribution layer forming a plurality of conductive pathways and one or more passive electrical components positioned within the redistribution layer, wherein the redistribution layer electrically couples the means for computing with the circuit.

### BRIEF DESCRIPTION OF THE DRAWINGS

FIG. 1 illustrates a side cross section view of interposer system according to some embodiments

FIG. 2 illustrates an exemplary method of manufacturing an interposer system according to some embodiments.

FIG. 3A illustrates a side cross section view of initial portions of the interposer formed on a carrier according to some embodiments.

FIG. 3B illustrates a side cross section view of initial portions of the interposer with cavities formed therein according to some embodiments.

FIG. 3C illustrates a side cross section view of initial portions of the interposer with embedded passive electrical components according to some embodiments.

FIG. 3D illustrates a side cross section view of top portions of the interposer formed on the initial portions according to some embodiments.

FIG. 3E illustrates a side cross section view of one or more devices and backside portions of the interposer formed on the top and initial portions of the interposer according to some embodiments.

FIG. 3F illustrates a side cross section view of a substrate coupled to the interposer according to some embodiments.

### DETAILED DESCRIPTION OF THE INVENTION

In the following description, numerous details are set forth for purposes of explanation. However, one of ordinary skill in the art will realize that the invention can be practiced without the use of these specific details. Thus, the present invention is not intended to be limited to the embodiments shown but is to be accorded with the widest scope consistent with the principles and features described herein.

Embodiments are directed to an interposer system, method and device including an interposer including a redistribution layer having a plurality of conductive pathways and passive electrical components positioned within the redistribution layer, wherein the redistribution layer electrically couples electrical devices with the passive components and/or a substrate. Specifically, the interposer is able to be an organic interposer whose redistribution layer has designed areas for receiving the passive components. As a result, the interposer system, method and device with embedded passive components has the benefit of enhanced power management. Specifically, the passive components embedded within the redistribution layer of the interposer (e.g. embedded high density capacitors) provide localized decoupling, reducing power supply noise and improving voltage stability across the integrated circuit. This is particularly important for high-frequency and high-performance applications. Further, the system, method and device improve space efficiency because, with the embedded components, the overall footprint of the electronic package is reduced. This allows for more compact and lightweight designs, which are essential for modern portable and high performance artificial intelligence (AI) datacenter devices. Also, the system, method and device improve signal integrity. In particular, the close proximity of the embedded passive components (e.g. capacitors, inductors) to the active components (e.g. microchips, chiplets) minimizes parasitic inductance and resistance, leading to better signal integrity and reduced electromagnetic interference (EMI). Additionally, the system, method and device improve scalability and integration because the design can be scaled to accommodate various passive component technologies (e.g. capacitor technologies, including multilayer ceramic capacitors (MLCCs), trench capacitors, and film capacitors). This flexibility allows for customization based on specific application requirements.

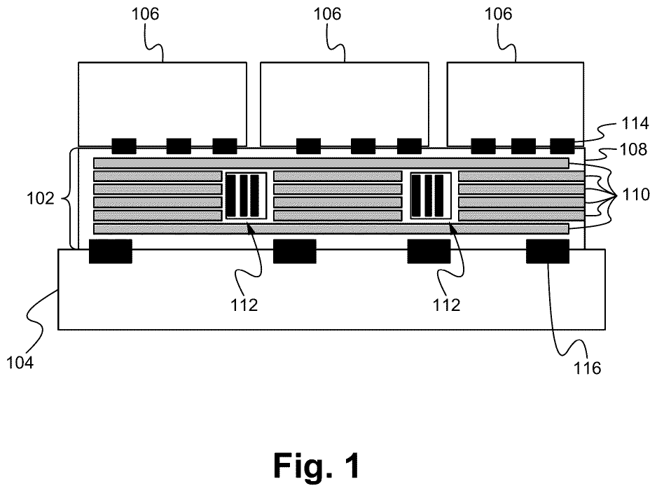

FIG. 1 illustrates a side cross section view of interposer system 100 according to some embodiments. As shown in FIG. 1, the system 100 comprises an interposer 102 coupled between a substrate 104 and one or more electrical devices 106. The devices 106 are able to comprise one or more of application specific integrated circuits, memories, memory microchips/chiplets, and/or computing microchips/chiplets. For example, one or more of the devices 106 are able to be high-performance artificial intelligence accelerator microchips. As another example, one or more of the devices 106 are able to be a part of a memory stack, be a chiplet having dedicated function(s) or be a general computing microchip. In some embodiments, the substrate 104 is a printed circuit board included an integrated circuit. Alternatively, the substrate 104 is able to comprise other types of substrates including circuits, passive electrical components, active electrical components or combinations thereof.

The interposer 102 includes a dielectric body 108 having an embedded redistribution layer 110 and one or more passive electrical components 112 positioned within the redistribution layer 110. In particular, because the interposer 102 includes the passive electrical components 112 are embedded within the redistribution layer 110 (and able to couple with the devices 106), the system 100 provides the benefit of being able to boost signal integrity for the devices 106 (without the high cost associated with silicon interposers). Indeed, in the case of capacitors being one or more of the passive electrical components 112, they are able to provide localized decoupling and power management. Thus, they are crucial for reducing impedance, minimizing signal noise, and improving overall performance in high-frequency applications. The interposer 102 is able to be an organic interposer such that the dielectric body 108 is able to comprise one or more of: composites or polymers, an epoxy, polyimide, glass-reinforced epoxy laminate (e.g., FR4), a bismaleimide-triazine (BT) resin organic material, or other suitable carbon-based or even non-carbon based materials or composites. Thus, “organic” interposer is able to differentiate from silicon and pure glass interposers. Alternatively, the interposer 102 is able to be a non-organic interposer (e.g. silicon, glass, or other non-organic interposers).

The redistribution layer 110 is able to comprise conductive routes or traces formed by copper or other conductive materials. As shown in FIG. 1, the redistribution layer 110 is able to comprise a plurality of sublayers stacked on top of each other such that together they form the redistribution layer 110. The redistribution layer 110 is designed such that conductive ends of the conductive routes at a topmost layer are electrically coupled with conductive ends of the conductive routes at a bottommost layer. As a result, the redistribution layer 110 is able to facilitate electrical connection between the device 106 and the substrate 104 on opposite sides of the interposer 102. Specifically, a top surface of the interposer 102 (and/or body 108) is able to comprise a plurality of conductive micro-bumps 114, wherein the conductive ends of the conductive routes at the topmost layer electrically couple with the devices 106 via the micro-bumps 114. Similarly, a bottom surface of the interposer 102 (and/or body 108) is able to comprise a plurality of conductive bumps 116 (e.g. Controlled Collapse Chip Connection (C4) bumps), wherein the conductive ends of the conductive routes at the bottommost layer electrically couple with the substrate 104 (and/or a circuit (not shown) positioned on the substrate) via the micro-bumps 114.

The passive electrical components 112 are able to comprise capacitors (e.g. high density capacitors, film capacitors, trench capacitors, MLCCs, or other types of capacitors), inductors, high density silicon electrical interconnects, other types of passive electrical components or a combination thereof. In some embodiments, the electrical components 112 are electrically coupled with one or more of the devices 106 via the redistribution layer 110. Specifically, the conductive routes of the redistribution layer 110 are able to electrically couple between the devices 106 (via the micro-bumps 114) and the electrical components 112. Alternatively, one or more of the electrical components 112 are able to be electrically coupled with one or more of the devices 106 without using the redistribution layer 110. Specifically, the one or more of the components 112 are able to be electrically coupled with the micro bumps 114 and thereby electrically coupled with the device(s) 106. In such cases, instead of being covered by one or more layers of the redistribution layer 110 (e.g. layers between the component 112 and the top surface of the body 108 or bottom of the micro bumps 114), the passive electrical components 112 are positioned adjacent to the top surface/micro bumps 114. Alternatively, when one or more of the components are high density silicon interconnect, these interconnects are able to electrically couple with the devices 106 (via the micro bumps 114) and/or electrically couple one or more of the other passive electrical components 112 with the with devices 106 (via the micro bumps 114).

In addition to being positioned within reserved gaps between the conductive routes of the redistribution layer 110, one or more of the components 112 are able to be positioned adjacent/proximate to the devices 106 to which they are electrically coupled. Thus, by selecting/positioning the reserved gaps/components 112 near the devices to which they are electrically coupled, the system 100 is able to provide the benefit of minimizing RC delay and parasitic effects that can greatly hamper high-performance microchips. Although as shown in FIG. 1, the system 100 comprises three devices 106, six redistribution layers 110 and two passive electrical components 112, more or less devices 106, redistribution layers 110 and/or passive electrical components 112 are contemplated.

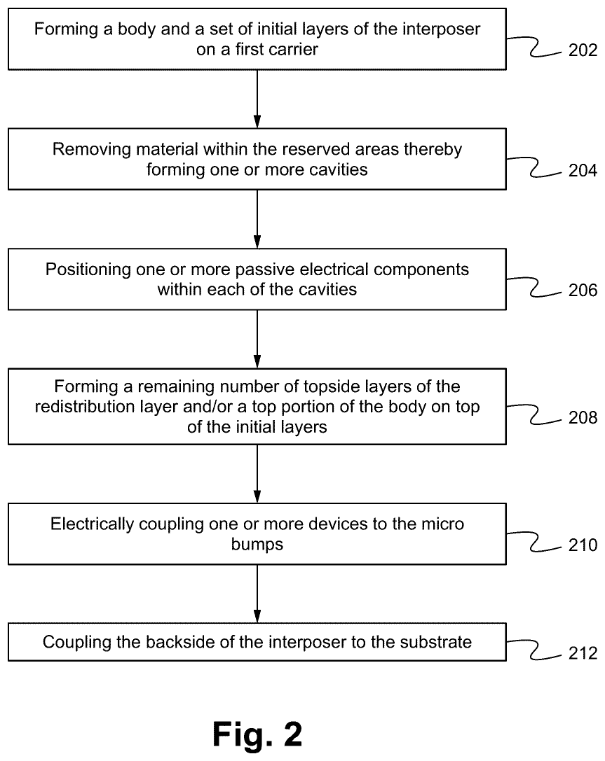

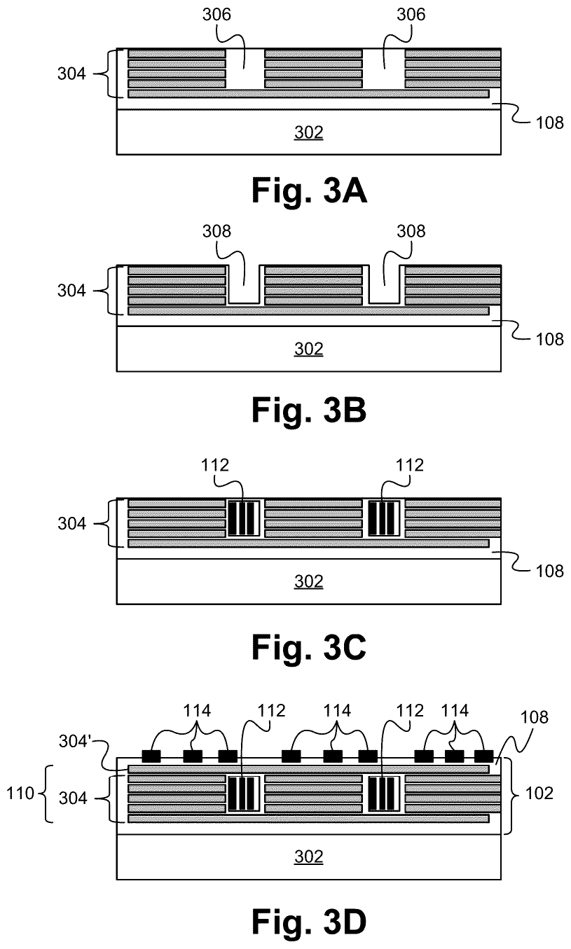

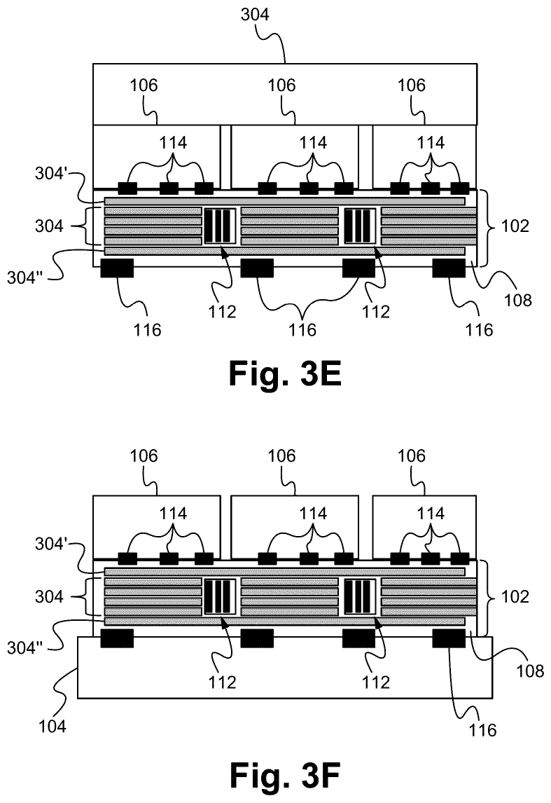

FIG. 2 illustrates an exemplary method of manufacturing an interposer system 200 according to some embodiments. An exemplary result produced by each step of the method 200 is illustrated in FIGS. 3A-3F. As shown in FIG. 2 and FIG. 3A, a body 108 and a set of initial layers 304 of the interposer 110 are formed on a first carrier 302 at the step 202. The forming of the layers 304 is able to include the creation of the electrically conductive interconnects forming vertical and/or horizontal conductive pathways through the interposer 102. As shown in FIG. 3A, the initial layers 304 are formed such that one or more areas 306 are reserved (e.g. kept free from conductive routes/traces and/or only include dielectric material) for passive electronic components 112. Specifically, each of the initial layers 304 are able to be designed with these areas 306 in mind, such that the conductive routes/traces that form the initial layers 304 navigate around those areas 306.

Additionally, the position of the reserved areas 306 are able to be selected such that they are adjacent and/or proximate locations where the devices 106 will be coupled to the interposer 102. Although as shown in FIG. 3A, the initial layers 304 comprise 5 layers and two reserved areas 306, more or less reserved areas 306 and/or layers 304 are able to be used (e.g. 3 to 8 layers). As shown in FIG. 3B, the material within the reserved areas 306 is removed (e.g. patterned around and etched away) thereby forming one or more cavities 308 at the step 204. Specifically, as shown in FIG. 3B, one or more of the initial layers 304 are able to be positioned below the areas 306 (e.g. between the areas 306 and the carrier 302), but are not positioned above the areas 306 such that the cavities 308 are able to be formed without interfering with the initial layers 304.

As shown in FIG. 3C, one or more passive electrical components 112 are positioned within each of the cavities 308 at the step 206. Once in place within the cavities 308, the remaining space within the cavities 308 is able to be filled with a dielectric material. For example, trench capacitors are able to be formed in the cavities 308 by filling them with high-k dielectric material and conductive plates to form the trench capacitor (and then adding one or more conductive connection pads for electrically coupling with the capacitor). As another example, pre-manufactured MLCCs are able to be inserted into the cavities 308 and then electrically coupled as desired. Alternatively, other methods of inserting passive electrical components 112 are able to be used. In some embodiments, positioning the components 112 within the cavities 308 is able to further comprise electrically coupling one or more of the components 112 to one or more of the initial layers 304 and/or to one or more of the other components 112. A remaining number of topside layers 304′ of the redistribution layer 110 and/or a top portion of the body 108 are formed on top of the initial layers 304 (and/or the components 112) at the step 208. In some embodiments, one or more micro bumps 114 are formed on and/or in a top surface of the interposer 102 (e.g. on/within the top portion of the body 108 of the interposer 102).

Although as shown in FIG. 3D, a single topside layer 304′ is added in step 208, more or less layers 304′ are able to be added. For example, zero topside layers 304′ are able to be added such that there are no layers 304′ between the components 112 and micro bumps 114, and thus one or more of the components 112 are able to be electrically coupled with the micro bumps 114 (without using the redistribution layer 110). Alternatively, one or more layers 304′ are able to be added that cover or partially cover one or more of the components 112, and one or more of the components 112 that are covered (or not covered) are able to electrically couple with the micro bumps 114 via the redistribution layer 110. In any case, step 208 is able to further comprise electrically coupling one or more of the components 112 (e.g. that were not electrically coupled in step 206) to the redistribution layer 110, the micro bumps 114, to other components 112 or a combination thereof. In particular, the components 112 are able to be electrically coupled with micro bumps 114 (directly, via the redistribution layer 110 and/or via high density silicon interconnect components 112) that are adjacent and/or proximate the components 112. As a result, when the devices 106 are coupled to the components 112 using those micro bumps 114, the distance between the devices 106 and the components 112 is minimized thereby reducing noise and other unwanted effects.

As shown in FIG. 3E, one or more devices 106 are electrically coupled to the micro bumps 114 at the step 210. After the devices 106 have been coupled, the first carrier 302 is able to be removed and a second carrier 304 is able to be attached to the devices 106 and/or topside of the interposer 102. Further, similar to step 208, a number of backside layers 304″ of the redistribution layer 110 and/or a bottom portion of the body 108 are formed on the bottom of the initial layers 304. Also, one or more bumps 116 are able to be formed on and/or in a bottom surface of the interposer 102 (e.g. on/within the bottom portion of the body 108 of the interposer 102). Although as shown in FIG. 3E, a single backside layer 304″ is added, more or less layers 304″ are able to be added. Additionally, step 210 is able to further comprise electrically coupling one or more of the bumps 116 with one or more of: the redistribution layer 110, the micro bumps 114, the devices 106, the components 112 or a combination thereof. Specifically, the redistribution layer 110 is able to form a network of conductive routes that couple one or more of the micro bumps 114/devices 106 with one or more of the bumps 116.

As shown in FIG. 3F, the backside of the interposer 102 is coupled to the substrate 104 at the step 212. In some embodiments, coupling the backside of the interposer 102 to the substrate 104 is able to further comprise electrically coupling one or more circuits/components on the substrate 104 to the bumps 116. As a result, the interposer 102 is able to provide an electrical connection between the devices 106, the substrate 104 (and electrical parts thereof) and/or the components 112. The second carrier 304 is then able to be removed. In some embodiments, the method is able to further comprise steps of underfill and encapsulation of the system 100 to protect the system 100 from environmental factors and/or mechanical stress.

The integrated circuit interposer system, method and device described herein provides numerous advantages. Specifically, the system, method and device has the benefit of enhanced power management. Specifically, the passive components embedded within the redistribution layer of the interposer (e.g. embedded high density capacitors) provide localized decoupling, reducing power supply noise and improving voltage stability across the integrated circuit. This is particularly important for high-frequency and high-performance applications. Further, the system, method and device improve space efficiency because, with the embedded components, the overall footprint of the electronic package is reduced. This allows for more compact and lightweight designs, which are essential for modern portable and high performance AI datacenter devices. Also, the system, method and device improve signal integrity. In particular, the close proximity of the embedded passive components 112 (e.g. capacitors, inductors) to the active components 106 (e.g. microchips, chiplets) minimizes parasitic inductance and resistance, leading to better signal integrity and reduced electromagnetic interference (EMI). Additionally, the system, method and device improve scalability and integration because the design can be scaled to accommodate various passive component technologies (e.g. capacitor technologies, including MLCCs, trench capacitors, and film capacitors). This flexibility allows for customization based on specific application requirements.

While the system, method and device has been described with reference to numerous specific details, one of ordinary skill in the art will recognize that the invention can be embodied in other specific forms without departing from the spirit of the invention. Thus, one of ordinary skill in the art will understand that the invention is not to be limited by the foregoing illustrative details. Further, it should be noted that although not described in detail for the sake of brevity, the system 100 and/or the parts thereof (e.g. devices, 106, substrate 104, interposer 102) are able to include or be a part of one or more of an integrated circuit, a software defined network, a top of rack switch, a network interface, additional memory, additional processors, I/O device(s), buses and/or a storage device. Additional memory and/or the memory described herein is able to be any conventional computer memory known in the art such as, but not limited to, a hard drive, DRAM, RAM, SRAM, CDROM, CDRW, DVD, DVDRW, flash memory card or any other storage device. An example of a network interface includes a network card connected to an Ethernet or other type of LAN. The I/O device(s) are able to include one or more of the following: keyboard, mouse, monitor, display, printer, modem, touchscreen, button interface and other devices. An operating system(s), graphical user interface(s), application(s), module(s) and/or other software on the system 100 (and/or parts thereof) are able to be stored in the memory and/or additional memory and/or storage device and processed as software is typically processed via the processors and/or additional processors of the system 100. The processes are able to be implemented via hardware, software, firmware and/or a combination of two or more of hardware, software and firmware such as memory, software/firmware and/or processors to execute the software/firmware stored on the memory in order to perform the functions of the processes.

We claim:

1. An integrated circuit system, the system comprising:
a substrate including a circuit;
one or more electrical devices; and
an organic interposer electrically coupled with the electrical devices via a plurality of micro-bumps and electrically coupled with the substrate via a plurality of electrical contacts, the organic interposer including a redistribution layer forming a plurality of conductive pathways and one or more passive electrical components positioned within the redistribution layer, wherein the redistribution layer electrically couples the electrical devices with the circuit.

2. The system of claim 1, wherein the passive electrical components comprise high-density capacitors.

3. The system of claim 2, wherein the high-density capacitors are coupled with the electrical devices via the conductive pathways of the redistribution layer.

4. The system of claim 2, wherein the high-density capacitors are coupled with the electrical devices via the micro-bumps.

5. The system of claim 3, wherein each high-density capacitor of the high-density capacitors is positioned within the redistribution layer adjacent to one of the electrical devices to which the high-density capacitor is electrically coupled.

6. The system of claim 5, wherein the electrical devices comprise at least one of computing chiplets and memory chiplets.

7. The system of claim 6, wherein the organic interposer is formed of one of polyimide and flame retardant 4.

8. The system of claim 7, further comprising one or more high density silicon electrical interconnects embedded within the redistribution layer and electrically coupled with the electrical devices.

9. The system of claim 8, wherein the electrical contacts comprise a plurality of controlled collapse chip connection bumps.

10. An organic interposer for use in a high-performance computing circuits, the organic interposer comprising:
an organic body having a top surface including a plurality of micro-bumps and a bottom surface including a plurality of electrical contacts;
a redistribution layer formed within the organic body and including a plurality of conductive pathways; and
one or more passive electrical components positioned within the redistribution layer, wherein the redistribution layer electrically couples the micro-bumps with the electrical contacts.

11. The interposer of claim 10, wherein the passive electrical components comprise high-density capacitors.

12. The interposer of claim 11, wherein the high-density capacitors are coupled with the micro-bumps via the conductive pathways of the redistribution layer.

13. The interposer of claim 11, wherein the high-density capacitors are directly coupled with the micro-bumps.

14. The interposer of claim 12, wherein each high-density capacitor of the high-density capacitors is positioned within the redistribution layer adjacent to a set of the micro-bumps to which the high-density capacitor is electrically coupled.

15. The interposer of claim 14, wherein the organic body is formed of one of polyimide and flame retardant 4.

16. The interposer of claim 15, further comprising one or more high density silicon electrical interconnects embedded within the redistribution layer and electrically coupled with the micro-bumps.

17. The interposer of claim 16, wherein the electrical contacts comprise a plurality of controlled collapse chip connection bumps.

18. A method of fabricating an integrated circuit, the method comprising:
coupling a first surface of a body of an organic interposer to a carrier substrate;
depositing an initial set of redistribution layers within the body, the initial set of redistribution layers including a plurality of conductive pathways surrounding one or more reserved areas intended for one or more passive electrical components;
removing dielectric material from the one or more areas and embedding the passive electrical components within the initial set of redistribution layers within the reserved areas;
depositing a plurality of micro-bumps onto a second surface of the body of the organic interposer; and
electrically coupling one or more electrical devices to the micro-bumps.

19. The method of claim 18, wherein the passive electrical components comprise high-density capacitors.

20. The method of claim 19, further comprising electrically coupling the micro-bumps to the high-density capacitors such that the high-density capacitors are electrically coupled with the electrical devices via the micro-bumps.

21. The method of claim 19, further comprising, before depositing the plurality of micro-bumps, covering a top of the initial set of redistribution layers and at least one of the high-density capacitors with a top set of redistribution layers.

22. The method of claim 21, further comprising electrically coupling the redistribution layer to the micro-bumps and the high-density capacitors such that the high-density capacitors are electrically coupled with the electrical devices via the redistribution layer and the micro-bumps.

23. The method of claim 21, wherein the embedding the passive electrical components within the initial set of redistribution layers comprises positioning each high-density capacitor of the high-density capacitors adjacent to one of the electrical devices to which the high-density capacitor is electrically coupled.

24. The method of claim 23, further comprising:
removing the carrier substrate from the first surface of the body;
couple another carrier substrate with the second surface;
covering a bottom of the initial set of redistribution layers with a bottom set of redistribution layers, wherein the initial set, the bottom and the top of the redistribution layers form a full redistribution layer;
depositing a plurality of electrical contacts on the first surface of the body; and
electrically coupling the electrical contacts with the one or more devices via the full redistribution layer.

25. The method of claim 24, wherein the electrical devices comprise at least one of computing chiplets and memory chiplets.

26. The method of claim 25, wherein the organic interposer is formed of one of polyimide and flame retardant 4.

27. The method of claim 26, further comprising embedding one or more high density silicon electrical interconnects within the reserved areas of the redistribution layer and electrically coupling the high density silicon electrical interconnects with the electrical devices.

28. The method of claim 27, wherein the electrical contacts comprise a plurality of controlled collapse chip connection bumps.

29. An integrated circuit system, the system comprising:
means for supporting a circuit including a circuit;
means for computing; and
organic means for electrically coupling electrically coupled with the means for computing via a plurality of micro-bumps and electrically coupled with the means for supporting via a plurality of electrical contacts, the means for electrically coupling including a redistribution layer forming a plurality of conductive pathways and one or more passive electrical components positioned within the redistribution layer, wherein the redistribution layer electrically couples the means for computing with the circuit.
